(19) United States
(12) Patent Application Publication
(10) Pub. No.: US 2008/0092093 A1
(43) Pub. Date: Apr. 17, 2008

(54) Register Transfer Level (RTL) Test Point Insertion Method to Reduce Delay Test Volume

(75) Inventors: Kedarnath Balakrishnan, Austin, TX (US); Lei Fang, Blacksburg, VA (US)

Correspondence Address: NEC LABORATORIES AMERICA, INC., 4 INDEPENDENCE WAY, Suite 200, PRINCETON, NJ, 08540, US

(73) Assignee: NEC LABORATORIES AMERICA, INC., Princeton, NJ (US)

(21) Appl. No.: 11/858,216

(22) Filed: Sep. 20, 2007

Related U.S. Application Data
(60) Provisional application No. 60/829,171, filed on Oct. 12, 2006.

(51) Int. Cl. G01R 31/3185

(52) U.S. Cl. 716/4

(57) ABSTRACT

A method includes inserting test points into a circuit for reducing the number of specified bits required for transition fault testing of the circuit by reducing the dependency of a second time-frame pattern of the circuit on a first time-frame pattern of the circuit. Preferably, inserting the test points includes controlling directly scan flip-flops of the circuit in the second time-frame requiring a number of scan flip-flops to be specified in the first time-frame for reducing the number of specified bits to detect transition faults.

This application claims the benefit of U.S. Provisional Application No. 60/829,171, entitled “RTL TEST POINT INSERTION TO REDUCE DELAY TEST VOLUME”, filed on Oct. 12, 2006, the contents of which is incorporated by reference herein.

This application is also related to U.S. patent application Ser. No. 11/851,137, entitled “PARTIAL ENHANCED SCAN TECHNIQUE FOR TRANSITION DELAY TEST PATTERNS”, filed on Sep. 6, 2007, an to U.S. Provisional Application No. 60/829,183, entitled “LOW OVERHEAD PARTIAL ENHANCED SCAN TECHNIQUE FOR COMPACT AND HIGH FAULT COVERAGE TRANSITION DELAY TEST PATTERNS”, both of which are also incorporated by reference herein.

### BACKGROUND OF THE INVENTION

The present invention relates generally to testing of chips for performance related failures, and, more particularly, to a method that register transfer level RTL test point insertion to reduce delay test volume.

The following works by others are mentioned in the application and referred to by their associated reference:
[1] S. Boubezari and E. Cerny et. al, “Testability Analysis and Test-Point Insertion in RTL VHDL Specifications for Scan-Based BIST,” IEEE Transactions on CAD, vol. 18, no. 9, pp. 1327-1340, September 1999.
[2] S. Roy, “Insertion of Test points in RTL Designs”, U.S. Pat. No. 6,301,688.
[3] S. Roy, G. Guner and K.-T. Cheng, “Efficient Test Mode Selection and Insertion for RTL-BIST,” in Proc. of International Test Conference, 2000, pp. 263-272.
[4] J. Carletta and C. Papachristou, “Testability Analysis and Insertion for RTL Circuits Based on Pseudorandom BIST,” in Proc. IEEE International Conference on Computer Design, 1995, pp. 162-167.
[5] Chih-Chang Lin; Marek-Sadowska, M.; Kwang-Ting Cheng; Lee, M. T.-C., “Test-point insertion: scan paths through functional logic”, IEEE Transactions on CAD, Volume 17, No. 9, September 1998 pp: 838-851.
[6] S. Wang and S. T. Chakradhar, “A Scalable Scan Path Test Point Insertion Technique to Enhance Delay Fault Coverage for Standard Scan Designs,” IEEE Transactions on CAD, vol. 25, no. 8, pp. 1555-1564, August 2006.

With Manufacturing test of current generation complex integrated chips is a critical part of the design process. At sub-micron technology nodes, new fault models are required to explain the defects that occur during the manufacturing process and to maintain good test quality, test generation is required for many fault models. Scan-based delay testing (esp. transition fault testing) has become an integral part of the structural Design-for-Test (DFT) flow. However, the test data volume required for delay testing is usually much higher than the test data volume required for traditional stuck-at fault testing. Moreover, the memory present in external automated test equipment (ATE) to store test data has not kept pace with the explosion in test data volume.

Scan-based transition fault testing has become popular to attain good test quality in current generation circuits. Detecting a transition delay fault requires application of two test patterns; the first one to initialize the desired value in the target circuit line and the second pattern to launch the transition at the circuit line and propagate it to one or more primary outputs or scan flip-flops. There are two popular approaches to apply transition tests in full scan environments and they differ in the way the second pattern is derived from the first pattern. The first pattern in both the approaches is shifted in through the scan chains similar to stuck-at pattern testing. In the launch-on-shift (LOS) or skewed load approach, the second pattern is obtaining by shifting the first pattern one more clock cycle. In the launch-on-capture (LOC) or broadside approach, the second pattern is the circuit response to the first pattern. Hence, in both of the above approaches, because of the dependency of the second pattern, the possible combinations of two patterns that can be applied to the circuit is restricted. Hence transition fault coverage is significantly lower than stuck-at fault coverage. One way to remove the dependency is to use two separate flip-flops in the scan cell to store the values of the first and second time frames. However, this “enhanced scan” approach requires very high hardware overhead as compared to normal scan. The LOS approach has another disadvantage that it requires the scan enable signal to be shifted at system clock (to get the second pattern) which involves more design and hardware overhead. In this work, we assume that a LOC based approach is used for applying transition delay test patterns to the circuit.

Test Point Insertion is a technique that has been traditionally used to improve the fault coverage of designs with very low fault coverage due to their structure. By inserting test points at the input (output) path of the target fault, controllability (observability) is improved and test generation for the fault is made easier. The parts of the gate level netlist that are difficult to control or observe i.e., where test points need to be inserted, can be identified using either the structural information or test generation based techniques or a combination of the two. The disadvantage of adding test points is that they modify the functional path of the design resulting in area as well as timing/delay overhead. However, if test points can be identified and inserted at the Register-Transfer Level of design abstraction, the area and delay overheads can be absorbed during logic synthesis to the gate level.

Identifying test points at the RT Level is hard since structural information is absent. Depending on the synthesis constraints, the same RT Level design can map into several gate level structures. Previous work on RTL test point insertion has focused on improving the stuck-at fault coverage during Built-In Self-Test (BIST) [1], [3] and [5]. In all these techniques, test points are inserted in the functional path after performing testability analysis. Test points can also be inserted in the scan-path of the design, between two scan flip-flops in a scan chain. This type of test point is very effective in transition fault testing and has been proposed in [6]. Both these techniques use test point insertion at gate level to break the shift dependency between adjacent flip-flops in transition tests based on LOS approach.

Accordingly, there is a need for a new method to identify and insert test points at the register transfer level RTL to reduce the volume of scan-based transition test patterns.

### SUMMARY OF THE INVENTION

In accordance with the invention, a method includes inserting test points into a circuit for reducing the number of specified bits required for transition fault testing of the circuit by reducing the dependency of a second time-frame pattern of the circuit on a first time-frame pattern of the circuit. Preferably, inserting the test points includes controlling directly scan flip-flops of the circuit in the second time-frame requiring a number of scan flip-flops to be specified in the first time-frame for reducing the number of specified bits to detect transition faults.

In another aspect of the invention, a method includes inserting test points into a circuit for reducing the number of specified bits required for transition fault testing of the circuit by i) transforming the circuit into a conjunctive normal form representing each circuit element by a variable; ii) choosing a transition fault at one of the lines visible at a register transfer level of the circuit; iii) adding an excitation condition for the transition fault to the conjunctive normal form; iv) adding a propagation path to the conjunctive normal form to create a new conjunctive normal form; v) applying a satisfiability process to the new conjunctive normal form; and vi) inserting test point on flip-flop responsive the satisfiability score.

### BRIEF DESCRIPTION OF DRAWINGS

These and other advantages of the invention will be apparent to those of ordinary skill in the art by reference to the following detailed description and the accompanying drawings.

FIG. 1 depicts scan flip-flops to be specified to detect a transition fault for explaining test generation transition faults using launch-on-capture LOC (broadside) approach.

FIG. 2 depicts an exemplary test point insertion in accordance with the invention for the example of FIG. 1.

FIG. 3 depicts an alternative test point insertion in accordance with the invention, for the example of FIG. 1.

FIG. 4 is a diagram of a circuit for generating a select signal by using an additional scan flip-flop, in accordance with the invention.

FIG. 5 is a flow chart of the test point insertion method in accordance with the invention.

### DETAILED DESCRIPTION

The invention is a new method to identify and insert test points at the register transfer level RTL to reduce the volume of scan-based transition test patterns. Test points are inserted in the scan-paths and do not modify the functionality of the circuit. The dependency of the second pattern in a transition test is reduced using the proposed test points which significantly reduce the number of inputs (and flip-flops) that need to be specified to detect a particular fault. Reducing the specified bits for each fault, results in higher test pattern compaction as well as higher test compression. The inventive method uses a very fast Satisfiability (SAT) based process with rules depending on the function of the register transfer RT level component to identify scan flip-flops that are difficult to control. By inserting the test points identified using the invention, the data volume of transition test patterns can be reduced significantly while the impact on area and delay are negligible.

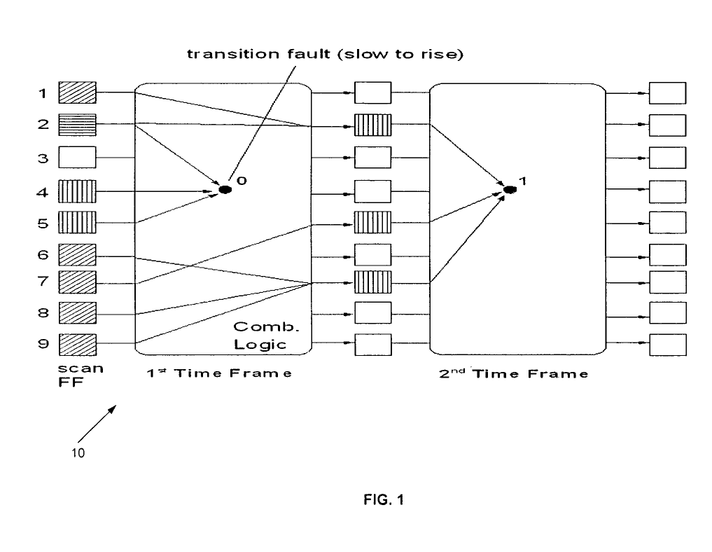

Test generation for transition faults using LOC (broadside) approach is somewhat similar to two time-frame sequential test generation. It is explained below using the example circuit in FIG. 1 which has been expanded into two time-frames. Without any loss of generality, assume that primary inputs and outputs are also scanned. In the first time frame, a pattern is generated to initialize the transition at the faulty gate. For a slow-to-rise (slow-to-fall) transition fault, this means justifying the faulty line to 0 (1). In the second time frame, a stuck-at-1 (stuck-at-0) test pattern is required to provoke the transition and sensitize a path to the circuit output. Since the values of the scan flip-flops required for the second time frame are captured from the circuit responses, more inputs and scan flip-flops need to be specified in the first time frame to detect the transition fault. This results in few chances of test pattern compaction and thus leads to higher test pattern volume.

This is illustrated by the diagram 10 of FIG. 1. To generate a transition test pattern for the slow-to-rise fault shown in FIG. 1, the line has to be justified to 0 in the first time frame and a stuck-at-1 test is required in the second time frame. For each of these steps, several scan flip-flops need to be specified. In FIG. 1, scan flip-flops 2, 4 & 5 are require to initialize the faulty node to 0 in the first time frame. In the second time frame, scan flip-flops 2, 5 & 7 are required to set the faulty node to 1 and propagate the fault to outputs. To capture the required value of scan flip-flop 2 in the second time frame, scan flip-flops 1 & 2 need to be set in the first time frame. Similarly to capture required values in scan flip-flops 5 & 7, scan flip-flops 7 and scan flip-flops 6, 8 & 9 need to be specified respectively in the first time frame. Hence a total of 8 scan flip-flops need to be specified to detect the given fault.

Boolean Satisfiability refers to the problem of determining a satisfying variable assignment for a Boolean function, or a proof that no such variable assignment exists in which case the function is unsatisfiable (UNSAT). A SAT problem takes as input a propositional formula that is represented in the conjunctive normal form (CNF). The CNF is a conjunction of several clauses, each of which is a disjunction of literals. A literal is a variable in its positive or negative polarity.

Generally any circuit representing a Boolean function can be transformed into a propositional formula. For instance, a two input AND gate with input a, b and output o can be represented as (a+ō)(b+ō)(ā+ b̅+o). All circuit elements can be transformed in a similar manner. Test generation for a circuit can also be transformed into a Boolean propositional formula. Each circuit element is represented in one or more clauses by using input/output propagation rules. The justification and propagation events for a fault are added as Boolean implications. SAT solvers can then be used to either find a satisfying variable assignment (if a test exists) for the propositional formula or prove that the fault is untestable if the formula is unsatisfiable.

Recent advances in SAT make it possible to identify the unsatisfiable segment if the SAT instance is unsatisfiable. From the UNSAT segment, a minimal set of clauses (called UNSAT core) can be extracted. This is explained in further detail in where a scheme for non-scan DFT based on extracting the UNSAT core is proposed. The UNSAT core is useful in identifying the regions of the circuit which are difficult to solve. Other information about the circuit can be obtained from the learned clauses which are generated by the SAT engine while solving a SAT instance during test generation. In this work, we use both the UNSAT core and learned clauses to identify specific characteristics of the circuit.

The key feature of the invention is to insert test points such that the number of specified bits required in transition fault testing is reduced. This is done by reducing the dependency of the second time-frame pattern on the first time-frame pattern. The scan flip-flops in the second time-frame which require a large number of scan flip-flops to be specified in the first time-frame are controlled directly, thereby reducing the number of specified bits to detect transition faults. This results not only in higher static and dynamic compaction but also higher test compression since the effectiveness of most compression schemes is directly related to the number of specified bits in test patterns. Under the invention, test points are inserted such that these flip-flops are directly loaded with the second time-frame value using a multiplexer. The test point is an extra flip-flop that stores the required second time-frame value.

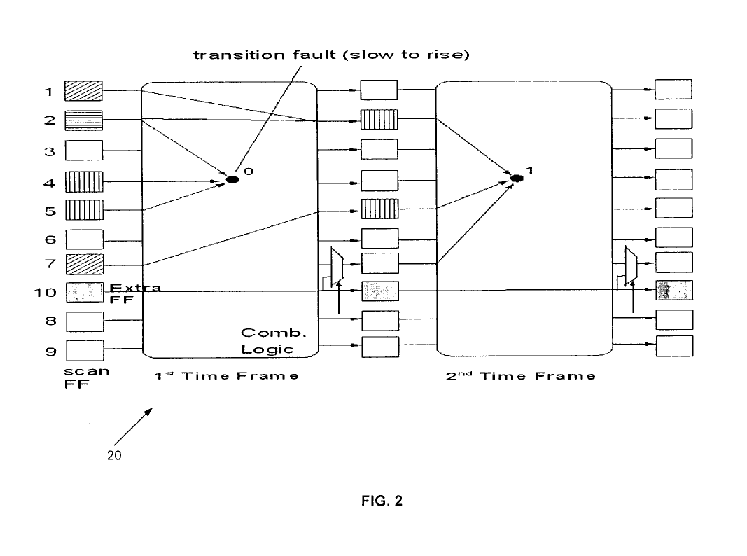

Consider again the example circuit 10 in FIG. 1. The diagram 20 of FIG. 2 shows an example of the inventive test point insertion where the second time-frame value required for scan flip-flop 7 is directly stored in scan flip-flop 10 in the first time-frame. Scan flip-flop 10 (fully shaded in FIG. 2) is the inserted test point. Flip-flops 6, 8 and 9 which needed to be specified earlier to detect the fault need not be specified after adding this test point. Hence the number of specified bits required to detect the same fault reduces to 6.

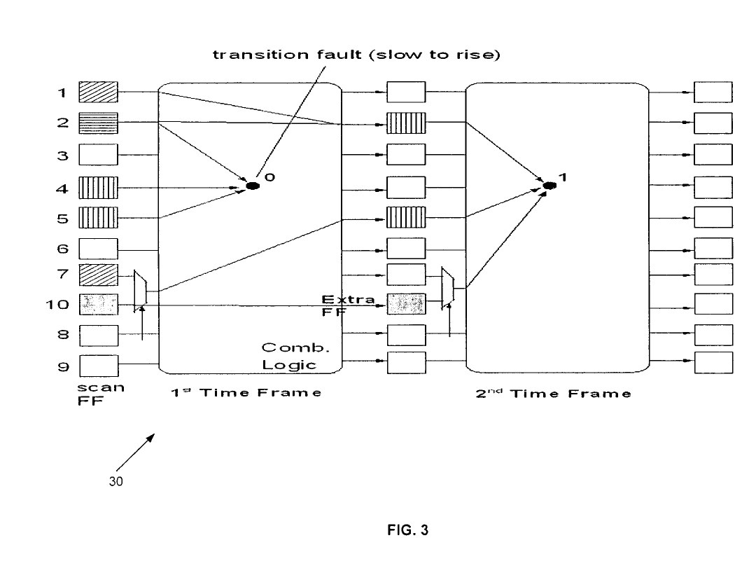

An alternative way of inserting test points in accordance with the invention is shown by the diagram 30 of FIG. 3, where the second time frame value required for the FF 7 is directly stored in FF 10 in the first time frame. FF 10 (shaded FF) is the inserted test point FF. With the inventive method, the number of specified bits required to detect the same fault reduces to 6.

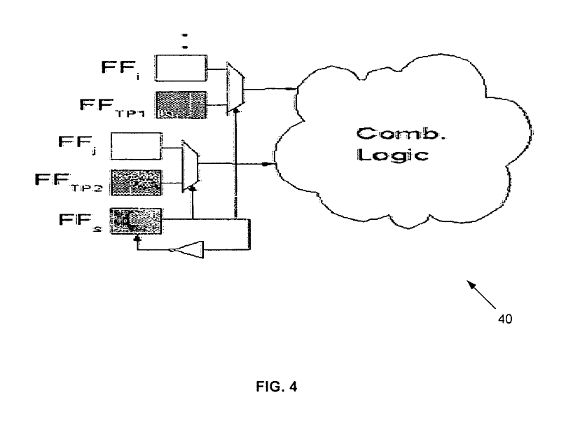

As mentioned above, the proposed test point is an additional flip-flop which is added to the scan chain so that it stores the required second time-frame value. As seen from FIG. 2, an additional multiplexer is required which selects between the combinational circuit output and the test point. The select input of the multiplexer need to be generated such that it has opposite values in the two time-frames. For the test point of FIG. 2, the select input should be 1 in the first time-frame and 0 in the second time-frame. If multiple test points are inserted in the design, the select inputs of the multiplexers for all the inserted test points can be shared. The logic circuit 40 of FIG. 4 shows a simple way of generating the select signal by using an additional scan flip-flop. In FIG. 3, FEᵢ and FFⱼ are selected to be inserted with test points which are FF_{TP1} and FF_{TP2} respectively. An additional flip-flop FF^{s} is used to generate the select signal. Hence, to insert k test points in the design, k+1 flip-flops and k multiplexers are required. The advantage of doing the insertion at RTL is that the extra area required for the multiplexers can be assimilated during logic synthesis.

Under the teachings of the present invention, test points are identified based on the functional information of RTL elements. If behavioral RTL is given, we analyze and elaborate the design into a temporary structural RTL netlist which gives a basic sense of circuit topology. A fast search is then done on this temporary structural RTL netlist to identify flip-flops that are (i) specified most in test patterns for transition faults and (ii) difficult to control in the second time-frame. Since adequate structural information is not available, the traditional controllability/observability analysis techniques cannot capture all the information. A functional approach is required and since RTL primitives like adders, multiplexers etc. can be easily transformed into CNF formula, a SAT based heuristic is used.

In the proposed scheme, a fast (and approximate) test generation for transition faults is done using SAT on the temporary RT Level netlist and the UNSAT and LEARNED clauses are utilized to identify potential flip-flops where test points can be inserted. A subset of transition faults is sampled for test generation to reduce the computation overhead. A score is maintained for each flip-flop in the design that indicates the number of times it has been utilized for test generation. For a sample of the transition faults in the temporary RT Level netlist, SAT instances for test patterns are generated and sent to the SAT solver. If the instances are satisfiable, the score of flip-flops appearing in the LEARNED clauses is increased. If the SAT instances are unsatisfiable, the score of flip-flops appearing in the UNSAT clauses are increased. The scan flip-flop with the highest score after the sampling is identified for test point insertion. Note that we can use weighted scores to differentiate between UNSAT and LEARNED clauses and the weights can be adjusted depending on the type of circuit, test generation ease etc. After each test point insertion, the clause used to represent constraints on the chosen flip-flop needs to be modified in the CNF representation of the circuit.

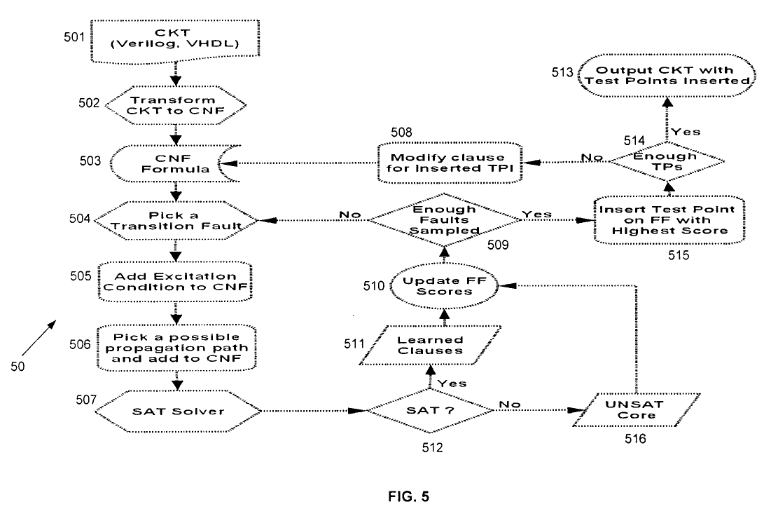

An exemplary flow chart 50 of the present test point insertion method is shown in FIG. 5. The high level description of the design (VHDL or Verilog) 501 is read and elaborated to a temporary RTL netlist. For LOC transition fault testing, the circuit is unrolled for two time-frames and transformed into a CNF formula F_{c} 502, 503, in which each circuit element is represented by a variable. A transition fault 504 at one of the lines visible at RTL, f, is chosen for test generation. The clause corresponding to its excitation condition is added to the CNF 505. A propagation path 506, p_{f}, for the fault effect is heuristically chosen and the constraints added to the original CNF to obtain a new CNF, F_{tf} corresponding to test generation for f.

The heuristic used for fault sampling and propagation path selection is explained below. A two phase sampling is used for selecting the faults. Initially, faults are selected randomly. In the second phase, faults are selected on lines with lowest scores. A score S_{g} is maintained for each line (variable) g, that represents the number of times it has appeared in UNSAT cores and LEARNED clauses. In this application, we define the score as S_{g}=U_{g}×w+L_{g} where U_{g} represents the number of times the line g occurs in UNSAT cores and L_{g} represents the corresponding number in LEARNED clauses. The weight, w depends on the test generation complexity of the circuit. In the proposed scheme, a probable propagation path for the sampled fault is selected using a greedy heuristic. The next node in the path is selected as the one with minimum S_{g} till the path reaches a primary or pseudo-primary output.

Note that F_{tf} actually represents a possible scenario to detect fault f. If F_{tf} is satisfiable 507, 512 then f is testable. The opposite is not true because there may be other sensitizable propagation paths. The key idea is not about checking whether F_{tf} is satisfiable but to locate the appropriate parts of the circuit that hinder test generation. If F_{tf} is unsatisfiable, an UNSAT core is extracted 516. On the other hand, if F_{tf} is satisfiable, a set of conflict LEARNED clauses 511 are obtained. Both the UNSAT core and conflict LEARNED clauses represent the difficulty of test pattern generation and the scores 510 for each line are updated appropriately. After enough faults have been sampled 509, the state element which has the highest score 515 is selected as the candidate for test point insertion. Since inserting a test point will change the testability of the circuit, if multiple test points are inserted 514, the test points need to be added iteratively. In each iteration, only one flip-flop is selected to add the test point. The CNF for the circuit F_{c} is updated with this test point for the new iteration 508. If enough test points Ts 514 are arrived at, then an output circuit with test points inserted is obtained 513.

In summary, the inventive insertion methodology with RTL level test points provides delay testing data reduction. When taking into account a high level design, a subset of flip-flops are identified as test points at RTL level using satisfiability. Extra flip-flops are inserted at these test points to improve the testability of the circuit. The original design along with the test points are synthesized together to a gate level netlist. Experiments on several benchmark designs and industry designs demonstrate that a very significant delay testing data volume reduction is achievable without violating the timing constraints, while still maintaining the minimum area overhead.

The present invention has been shown and described in what are considered to be the most practical and preferred embodiments. It is anticipated, however, that departures may be made there from and that obvious modifications will be implemented by those skilled in the art. It will be appreciated that those skilled in the art will be able to devise numerous arrangements and variations which, although not explicitly shown or described herein, embody the principles of the invention and are within their spirit and scope.

What is claimed is:

1. A method comprising the step of:
inserting test points into a circuit for reducing the number of specified bits required for transition fault testing of the circuit by reducing the dependency of a second time-frame pattern of the circuit on a first time-frame pattern of the circuit.

2. The method of claim 1, wherein the step of inserting test points comprises controlling directly the scan flip-flops of the circuit in the second time frame which depend on scan flip-flops to be specified in the first time frame for reducing the number of specified bits to detect transition faults.

3. The method of claim 2, wherein the scan flip-flops are directly loaded with a value for the second time-frame using a multiplexer.

4. The method of claim 3, wherein the test point is a flip-flop that stores the value for the second time frame.

5. The method of claim 1, wherein the step of inserting test points comprises identifying and inserting test points at register transfer level (RTL level) of design for reducing the volume of scan based transition test patterns without any impact on timing and area of the design.

6. The method of claim 1, wherein dependency of a second time-frame pattern of the circuit in transition testing is reduced using the test points which the number of inputs and flip-flops that need to be specified to detect a particular fault.

7. The method of claim 1, wherein scan flip-flops difficult to control are identified using a satisfiability SAT engine based on the function of the register level configuration.

8. The method of claim 1, wherein the step of inserting test points comprises transforming the circuit after two time frames into a conjunctive normal form in which each circuit element is represented by a variable.

9. The method of claim 8, wherein the step of inserting test points comprises choosing for test generation a transition fault at one of the lines visible at a register transfer level of the circuit.

10. The method of claim 9, wherein the step of inserting test points comprises adding an excitation condition for the transition fault to the conjunctive normal form.

11. The method of claim 10, wherein the step of inserting test points comprises adding a possible propagation path to the conjunctive normal form to create a new conjunctive normal form.

12. The method of claim 11, wherein the step of inserting test points comprises applying a satisfiability process to the new conjunctive normal form.

13. The method of claim 12, wherein the step of inserting test points comprises updating flip-flop scores responsive to the satisfiability process.

14. The method of claim 13, wherein the step of inserting test points comprises inserting test point on flip-flop with highest score from the satisfiability process.

15. The method of claim 1, wherein the step of inserting test points comprises controlling directly the scan flip-flops of the circuit in the second time frame which depend on scan flip-flops to be specified in the first time frame for reducing the number of specified bits to detect transition faults thereby improving test data compression.

16. A method comprising the step of:
inserting test points into a circuit for reducing the number of specified bits required for transition fault testing of the circuit by:
i) transforming the circuit into a conjunctive normal form representing each circuit element by a variable;
ii) choosing a transition fault at one of the lines visible at a register transfer level of the circuit;
iii) adding an excitation condition for the transition fault to the conjunctive normal form;
iv) adding a propagation path to the conjunctive normal form to create a new conjunctive normal form;
v) applying a satisfiability process to the new conjunctive normal form; and
vi) inserting a test point on a state element of the circuit responsive to the satisfiability process.
